(19) United States
(12) Patent Application Publication
(10) Pub. No.: US 2024/0243143 A1
(43) Pub. Date: Jul. 18, 2024

(54) Boron-Coated Back-Illuminated Image Sensor With Fluoride-Based Anti-Reflection Coating

(71) Applicant: KLA Corporation, Milpitas, CA (US)

(72) Inventors: Evgeniia Butaeva, San Jose, CA (US); Sisir Yalamanchili, Fremont, CA (US); Larissa Juschkin, Pleasanton, CA (US); John Fielden, Los Altos, CA (US); Ting Fung Chung, Milpitas, CA (US); Francisco Kole, San Jose, CA (US)

(21) Appl. No.: 18/391,595

(22) Filed: Dec. 20, 2023

Related U.S. Application Data
(60) Provisional application No. 63/438,788, filed on Jan. 12, 2023.

(51) Int. Cl. H01L 27/146; G01N 21/95

(52) U.S. Cl. CPC H01L 27/1462; G01N 21/9501; H01L 27/14636; H01L 27/1464; H01L 27/14685; G02B 1/11

(57) ABSTRACT

Back-illuminated image sensors for detecting short wavelength radiation (e.g., deep ultraviolet (DUV) and vacuum ultraviolet (VUV) light) include a semiconductor membrane, circuit elements formed on a frontside surface of the semiconductor membrane, and a pure boron coating on the backside surface of the semiconductor membrane. A two-part anti-reflective coating is formed over the pure boron coating and includes a thin oxide or nitride protection layer disposed between the pure boron coating and a fluoride-based anti-reflection layer. A method for fabricating the image sensors may include performing plasma atomic layer deposition (plasma ALD) processes to sequentially generate the pure boron coating, the oxide/nitride protection layer and then the fluoride-based anti-reflection layer. The image sensors may be configured as charge coupled devices (CCDs), complementary metal oxide semiconductor (CMOS) sensors, or as photodiodes, and arranged as two-dimensional (2D) area sensors or a one-dimensional (1D) array sensors.

### RELATED APPLICATION

This application claims priority to U.S. Provisional Patent Application No. 63/438,788 entitled “METHODS OF IMPLEMENTING FLUORIDE BASED ANTI-REFLECTION COATINGS ON BACK-ILLUMINATED SENSOR WITH BORON LAYER”, which was filed on Jan. 12, 2023.

### FIELD OF DISCLOSURE

The present application relates to image sensors suitable for sensing radiation in deep UV (DUV) and vacuum UV (VUV), and to methods for fabricating/producing such image sensors. Some embodiments of the sensors are suitable for sensing electrons and other charged particles. All of the sensors are suitable for use in photomask, reticle, or wafer inspection systems.

### RELATED ART

The integrated circuit industry requires inspection tools with increasingly higher resolution to resolve ever smaller features of integrated circuits, photomasks, reticles, solar cells, charge coupled devices etc., as well as detect defects whose sizes are of the order of, or smaller than, those feature sizes.

Inspection systems operating at short wavelengths, e.g., wavelengths shorter than about 250 nm, can provide such resolution in many cases. In other cases, electrons or other charged particles, such as helium (He) nuclei (i.e., alpha particles) may be used. Specifically, for photomask or reticle inspection, it is desirable to inspect using a wavelength identical, or close, to the wavelength that will be used for lithography, i.e., close to 193.4 nm for current generation lithography and close to 13.5 nm for future EUV lithography, as the phase-shifts of the inspection light caused by the patterns will be identical or very similar to those caused during lithography. For inspecting semiconductor patterned wafers, inspection systems operating over a relatively broad range of wavelengths, such as a wavelength range that includes wavelengths in the near UV, DUV, and/or VUV ranges, can be advantageous because a broad range of wavelengths can reduce the sensitivity to small changes in layer thicknesses or pattern dimensions that can cause large changes in reflectivity at an individual wavelength.

In order to detect small defects or particles on photomasks, reticles, and semiconductor wafers, high signal-to-noise ratios are required. High photon or particle flux densities are required to ensure high signal-to-noise ratios when inspecting at high speed because statistical fluctuations in the numbers of photons detected (Poisson noise) is a fundamental limit on the signal-to-noise ratio. In many cases, approximately 100,000 or more photons per pixel are needed. Because inspection systems are typically in use 24 hours per day with only short stoppages, the detectors are exposed to large doses of radiation after only a few months of operation.

A photon with a vacuum wavelength of 250 nm has energy of approximately 5 eV. The bandgap of silicon dioxide is about 10 eV. Although it may appear such wavelength photons cannot be absorbed by silicon dioxide, silicon dioxide as grown on a silicon surface must have some dangling bonds at the interface with the silicon because the silicon dioxide structure cannot perfectly match that of the silicon crystal. Furthermore, because the single dioxide is amorphous, there are likely also some dangling bonds within the material. In practice, there will be a non-negligible density of defects and impurities within the oxide, as well as at the interface to underlying semiconductor, that can absorb photons with deep UV wavelengths, particularly those shorter than about 250 nm in wavelength. Furthermore, under high radiation flux density, two high-energy photons may arrive near the same location within a very short time interval (nanoseconds or picoseconds), which can lead to electrons being excited to the conduction band of the silicon dioxide by two absorption events in rapid succession or by two-photon absorption.

A further requirement for sensors used for inspection, metrology and related applications is high sensitivity. As explained above, high signal-to-noise ratios are required. If the sensor does not convert a large fraction of the incident photons into signal, then a higher intensity light source would be required in order to maintain the same inspection or measurement speed compared with an inspection or metrology system with a more efficient sensor. A higher intensity light source would expose the instrument's optics and the sample being inspected or measured to higher light intensities, possibly causing damage or degradation over time. A higher intensity light source would also be more expensive or, particularly at DUV and VUV wavelengths, may not be available. Silicon reflects a high percentage of DUV and VUV light incident upon it. For example, near 193 nm in wavelength, silicon with a 2 nm oxide layer on its surface (such as a native oxide layer) reflects approximately 65% of the light incident on it. Growing an oxide layer of about 21 nm on the silicon surface reduces the reflectivity to close to 40% for wavelengths near 193 nm. A detector with 40% reflectivity is significantly more efficient than one with 65% reflectivity, but lower reflectivity, and hence higher efficiency, is desirable.

Anti-reflection (AR) coatings (aka, anti-reflection, anti-reflective or antiglare coatings) are commonly used on optical elements such as lenses and mirrors to increase efficiency by reducing the optical elements' reflectivity. However, many AR coating materials and processes commonly used for optical elements are often not compatible with silicon-based sensors. For example, electron and ion-assisted deposition techniques are commonly used to generate AR and other optical coatings. Such coating processes cannot generally be used to coat semiconductor devices because the electrons or ions can deposit sufficient charge on the surface of the semiconductor device to cause electrical breakdown, resulting in damage to the circuits fabricated on the semiconductor.

DUV and VUV wavelengths are strongly absorbed by silicon. Such wavelengths may be mostly absorbed within about 10 nm or a few tens of nm of the surface of the silicon. The efficiency of a sensor operating at DUV or VUV wavelengths depends on how large a fraction of the electrons created by the absorbed photons can be collected before the electrons recombine. Silicon dioxide can form a high-quality interface with silicon with a low density of defects. Most other materials, including many of those commonly used for anti-reflection coatings, if deposited directly on silicon, result in a very high density of electrical defects at the surface of silicon. A high density of electrical defects on the surface of silicon may not be an issue for a sensor intended to operate at visible wavelengths, as such wavelengths may typically travel about 100 nm or more into the silicon before being absorbed and may, therefore, be little affected by electrical defects on the silicon surface. However, DUV and VUV wavelengths are absorbed so close to the silicon surface that electrical defects on the surface and/or trapped charges within the layer (s) on the surface can result in a significant fraction of the electrons created recombining at, or near, the silicon surface and being lost, resulting in a low efficiency sensor.

U.S. Pat. Nos. 9,496,425, 9,818,887, and 10,121,914, describe boron-coated back-illuminated image sensors and methods of making image sensors that include at least one boron layer deposited on, at least, the exposed backside (light-receiving) surface of the image sensor that functions to increase the durability and quantum efficiency of the image sensor. Different ranges of temperature for deposition of the boron are disclosed, including a range of about 400-450° C., and a range of about 700-800° C. The inventors have discovered that one advantage of a higher deposition temperature for the boron, such as a deposition temperature between about 600° ° C. and about 900° ° C., is that, at such temperatures, boron diffuses into the silicon providing a very thin, heavily p-type doped silicon layer on the light-sensitive back surface. This p-type doped silicon layer is important for ensuring a high quantum efficiency to DUV and VUV radiation because it creates a static electric field near the surface that accelerates electrons away from the surface into the silicon layer. The p-type silicon also increases the conductivity of the back surface of the silicon, which is important for high-speed operation of an image sensor, since a return path is needed for ground currents induced by the switching of signals on electrodes on the front surface of the sensor. U.S. Pat. No. 11,114,491 describes image sensor structures with a very thin, low temperature (below 450° C.) epitaxial silicon grown over the back thinned surfaces of silicon sensors, prior to low temperature (below 450° C.) boron coating to achieve high quantum efficiency to DUV and VUV radiation because it can also create a static electric field near the surface that accelerates electrons away from the surface into the silicon layer. In all of these boron-coated back-illuminated image sensors, the boron coating increases the image sensors' durability by protecting against degradation caused by heavy doses of high energy radiation, such as DUV and/or VUV radiation.

As set forth above, silicon-based back-illuminated image sensors utilized for high energy wafer inspection applications (i.e., using wavelengths below 193 nm) require both a boron layer and an anti-reflection coating. That is, while the boron layer can improve the durability of these image sensors, an anti-reflection coating is required over the boron layer to improve the image sensors' quantum efficiency by increasing the amount of incident radiation received by the sensor (i.e., by decreasing the amount of radiation reflected from the silicon surface before it reaches the sensor's detection element). An ideal anti-reflection coating for such boron-coated image sensors would be one that can be safely formed over the boron layer and is transparent to wavelengths below 193 nm. Oxide-based anti-reflection coatings are used on boron-coated image sensors utilized to detect wavelengths above 193 nm, but oxide-based materials increasingly absorb radiation in inverse proportion to wavelengths below 193 nm. That is, the absorption of radiation by oxide-based anti-reflection coatings is very high at VUV wavelengths, such as 150 nm or below, as the photon energy at these wavelengths equals or exceeds the oxide material's band gap. Fluoride-based materials, such as magnesium fluoride (MgF₂) and calcium fluoride (CaF₂), are utilized to form anti-reflection coatings on optical elements used at wavelengths below 193 nm due to their higher band gap (i.e., in comparison to oxides). However, the use of such fluoride-based anti-reflection coatings on boron-coated image sensors is problematic because the fluoride-based atoms, ions, and free radicals involved in the fluoride-based material deposition procedures migrate into and damage the boron layer, thereby decreasing the durability of the image sensor. Other materials, such as metals, can be safely deposited on the boron layer without reducing the image sensor's durability, but are not transparent to wavelengths below 193 nm.

Therefore, a need arises for back-illuminated image sensors that are both durable and capable of sensing UV and/or VUV radiation with high quantum efficiency. In particular, what is needed is a method for generating back-illuminated image sensors that combine both the durability provided by a pure boron coating and the low reflectivity to UV/VUV radiation exhibited by fluoride-based anti-reflection coatings that overcomes some or all the above-mentioned fluoride-on-boron issues.

### SUMMARY OF THE INVENTION

The present invention is directed to a back-illuminated image sensor for deep ultraviolet (DUV) radiation and vacuum ultraviolet (VUV) radiation that includes a pure boron coating disposed on the backside surface of a semiconductor membrane (e.g., an epitaxial silicon layer) and a two-part anti-reflective coating that includes a protection layer disposed on the pure boron coating and a fluoride-based coating disposed on the protection layer. According to an aspect, the protection layer includes at least one of a thin oxide film (e.g., one or more of Al₂O₃, MgO, La₂O₃, Li₂O, CaO, BeO, and HfO₂) and/or a thin nitride film (e.g., one or more of AlN, Li₃N, LaN, Mg₃N₂, HAN and Ca₃N₂), wherein a total thickness of the oxide/nitride film(s) is within the range of 0.5 nm to 10 nm. Implementing the protection layer using oxide/nitride films that meet these specifications provides several advantages over other possible protection layer materials. First, when formed with a thickness of at least 0.5 nm, such oxide/nitride protection layers can be made thick enough to function as diffusion barriers that are capable of impeding the migration of fluoride ions/atoms/radicals from any fluoride-based material (e.g., one of AlF₃, MgF₂, CaF₂, LaF₃, LiF, and HfF₄) subsequently deposited/formed thereon to the boron coating, thus facilitating optimization of the anti-reflective characteristics of the fluoride-based AR coating while avoiding the above-mentioned fluoride-on-boron issues. Second, limiting the total oxide/nitride film thickness to 10 nm minimizes any parasitic absorption of DUV and/or VUV radiation of the oxide/nitride protection layer. Third, such oxide/nitride thin films can be safely and reliably formed with high precision on pure boron coatings using several well-established semiconductor fabrication processes including: physical vapor deposition (PVD) methods such as thermal or e-beam evaporation; chemical vapor deposition (CVD) methods such as atmospheric pressure chemical vapor deposition (APCVD), plasma enhanced chemical vapor deposition (PECVD), or low pressure chemical vapor deposition (LPCVD); atomic layer deposition (ALD) which can also be thermal or plasma enhanced; or molecular beam epitaxy (MBE)). Fourth, such oxide/nitride thin films provide excellent protection for the underlying pure boron coating, thereby facilitating the use of thinner pure boron coatings while increasing production yields and image sensor operating lifetimes. Accordingly, the two-part anti-reflective coating provides the back-illuminated image sensors with both the durability of a pure boron coating and the low reflectivity to UV/VUV radiation of a fluoride-based anti-reflection coating while overcoming some or all the above-mentioned fluoride-on-boron issues.

In a presently preferred embodiment, the oxide/nitride protection layer includes one of an Al₂O₃ or AlN thin film having a thickness in the range of 0.5 nm and 5 nm (and even more preferably 2 nm or less as process allows) that is formed on an upper surface of the pure boron coating, and the fluoride-based anti-reflection layer is formed on the Al₂O₃ or AlN protection layer. An advantage to utilizing Al₂O₃ and AlN in the formation of the oxide/nitride protection layer is that both of these materials can be deposited with high precision (i.e., with atomic control over thickness) using well-established ALD processes. Moreover, their scalability and production worthiness on large area wafers, especially of Al₂O₃, is very well known. The deposition of other oxide/nitride materials using ALD is less common, but research literature indicates they may be fabricated with sufficient precision at smaller (lab) scales, and so may be practical in production in the future. In embodiments that utilize an Al₂O₃ and/or AlN protection layer, from among the various materials listed herein for forming the fluoride-based anti-reflection layer, MgF₂ is presently preferred, followed by CaF₂ and then the other fluoride-based material options.

In a generalized embodiment a method for fabricating the above-mentioned back-illuminated image sensors includes forming frontside circuit structures on a frontside (first) surface of a semiconductor membrane, then forming a pure boron coating on a backside (second) surface of the semiconductor membrane, then forming an oxide/nitride protective layer on the pure boron coating with an initial thickness in the range of 0.5 nm to 50 nm, and then forming a fluoride-based anti-reflection coating on the protective layer. By forming the oxide/nitride protective layer between the pure boron coating and the fluoride-based anti-reflection coating, the method facilitates the production of back-illuminated image sensors exhibiting both the durability of a pure boron coating and the low reflectivity to UV/VUV radiation exhibited by fluoride-based anti-reflection coatings while overcoming some or all the above-mentioned fluoride-on-boron issues.

In some embodiments forming the pure boron coating involves depositing amorphous boron on the backside surface until a total thickness in the range of 2 nm to 20 nm is achieved. In some embodiments a high temperature deposition process is utilized to form the pure boron coating with a suitably high quality, which requires the completion of front-end circuit elements (e.g., forming metal interconnects over the previously formed front-end circuit structures) after the boron formation process. In other embodiments the pure boron coating may be formed with a suitably high quality using high temperature deposition process, thereby facilitating the completion of front-end circuit elements before the boron formation process.

In some embodiments forming the protective layer involves depositing one or more of Al₂O₃, MgO, La₂O₃, Li₂O, CaO, BeO, HfO₂, AlN, Li₃N, LaN, Mg₃N₂, HfN and/or Ca₃N₂ directly onto the pure boron coating. In alternative specific embodiments, the oxide/nitride deposition process involves performing one of a PVD, CVD, ALD or MBE deposition process. An initial thickness of the protection layer (i.e., immediately after deposition and before formation of the fluoride-based anti-reflective coating) is determined by the process utilized to form the fluoride-based anti-reflective coating. In some embodiments the fluoride-based anti-reflective coating is formed by depositing a fluoride-based materials (e.g., AlF₃, MgF₂, CaF₂, LaF₃, LiF and/or HfF₄) onto the protection layer using, e.g., a PVD, CVD, ALD or MBE deposition process. In these cases, because the thickness of the protection layer does not change significantly during formation of the fluoride-based anti-reflective coating, the protection layer is formed with a relatively thin initial thickness (e.g., in the range of 0.5 nm to 10 nm). In other embodiments the fluoride-based anti-reflective coating is formed using a fluorination process in which the protection layer is exposed to one or more fluorine-containing gases (e.g., one or more of F₂, HF, XeF₂, CH₃F, SF₆, CF₄, NbF₅, and WF₆) under conditions that convert an upper region (e.g., uppermost layers) of the protection layer from oxide/nitride material to fluoride-based material (i.e., such that an upper portion of the protection layer is used/converted to form the fluoride-based anti-reflective coating). In these cases, because the thickness of the protection layer is significantly reduced during formation of the fluoride-based anti-reflective coating, the protection layer is formed with a relatively thick initial thickness (e.g., in the range of 10 nm to 50 nm, depending on the targeted final thickness of the protection layer and the targeted final thickness of the fluoride-based anti-reflective coating. In some embodiments, the fluorination process is performed in a plasma chamber to enhance the conversion process.

The fabrication methods described herein may be incorporated into the fabrication flows associated with several types of boron-coated, back-illuminated image sensors. For example, the frontside circuit elements may be configured to implement charge coupled devices (CCDs), complementary metal oxide semiconductor (CMOS) imagers and/or photodiodes, and include other semiconductor devices such as transistors, diodes, resistors and capacitors that are configured to collectively perform image sensor operations. The fabrication methods may be used in combination with image sensor fabrication processes in which a silicon layer or SOI structure are partially or fully back-thinned and through-silicon vias are formed before formation of the pure boron layer.

By utilizing any of the fabrication methods mentioned above and/or described in additional detail below, the present invention provides back-illuminated image sensors capable of sensing DUV and VUV radiation (e.g., radiation below 193 nm) that exhibit both longer operating lifetimes (i.e., due to the pure boron coating) and high quantum efficiency (i.e., due to the fluoride-based AR coating) while overcoming the above-mentioned fluoride-on-boron issues (i.e., due to the oxide/nitride protective layer). The present invention is also directed to back-illuminated image sensors incorporating at least one fluorine-based anti-reflection coating disposed over at least one pure boron layer, and to an inspection system utilizing such back-illuminated image sensor.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF FIGURES

FIG. 1 is a flow diagram showing a simplified back-illuminated image sensor and associated fabrication method according to embodiments of the present invention.

FIG. 2 is a flow diagram showing a simplified back-illuminated image sensor and an associated high-temperature boron fabrication method according to a specific embodiment of the present invention.

FIG. 3 is a flow diagram showing a simplified back-illuminated image sensor and an associated low-temperature boron fabrication method according to a specific embodiment of the present invention.

FIGS. 4A, 4B and 4C illustrate exemplary cross sections of a sensor back surface and describes the formation of a fluoride-based anti-reflection coating over an oxide/nitride protection layer and pure boron coating according to another embodiment.

FIGS. 5A, 5B and 5C illustrate another set of exemplary cross sections of a sensor back surface and describes the formation of a fluoride-based anti-reflection layer by partially fluorinating the upper portion of an oxide/nitride protection layer according to another embodiment of the present invention.

FIGS. 6A and 6B are cross-sectional views depicting simplified exemplary plasma-capable ALD deposition chambers utilized during at least the fluoride-based AR coating deposition process according to another embodiment of the present invention.

FIGS. 7A and 7B are cross-sectional side views showing back-thinned membrane image sensors fabricated on a silicon substrate utilizing partial wafer thinning according to associated embodiments of the present invention.

FIG. 8 is a cross-sectional side view showing a back-thinned image sensor fabricated on an SOI substrate utilizing full wafer thinning according to another embodiment of the present invention.

FIG. 9 is a simplified schematic diagram showing an inspection system that utilizes any of the back-illuminated image sensors described with reference to FIGS. 1-8 according to another embodiment of the present invention.

### DETAILED DESCRIPTION OF THE DRAWINGS

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

The following description is presented to enable one of ordinary skill in the art to make and use the disclosure as provided in the context of a particular application and its requirements. As used herein, directional terms such as “top,” “bottom,”, “front,” “frontside”, “backside,” “over,” “under,” “upper,” “upward,” and “lower” are intended to provide relative positions for purposes of description and are not intended to designate an absolute frame of reference. Various modifications to the preferred embodiment will be apparent to those with skill in the art, and the general principles defined herein may be applied to other embodiments. Therefore, the present disclosure is not intended to be limited to the embodiments shown and described but is to be accorded the widest scope consistent with the principles and novel features herein disclosed.

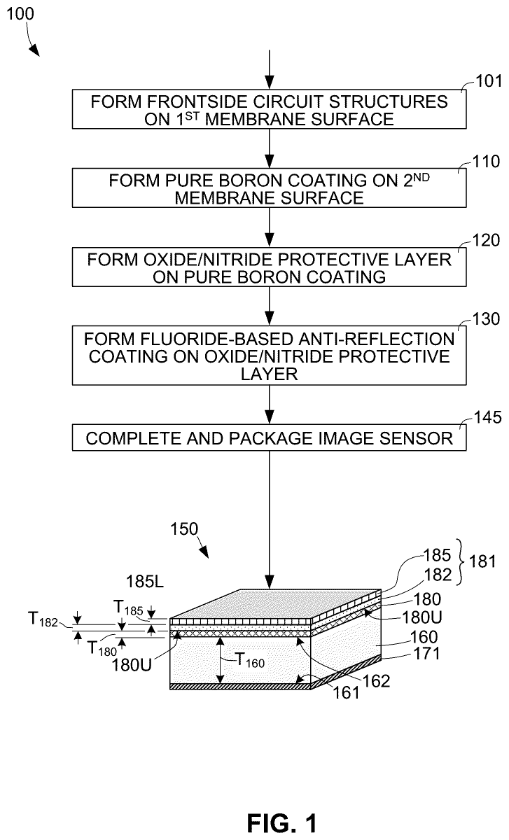

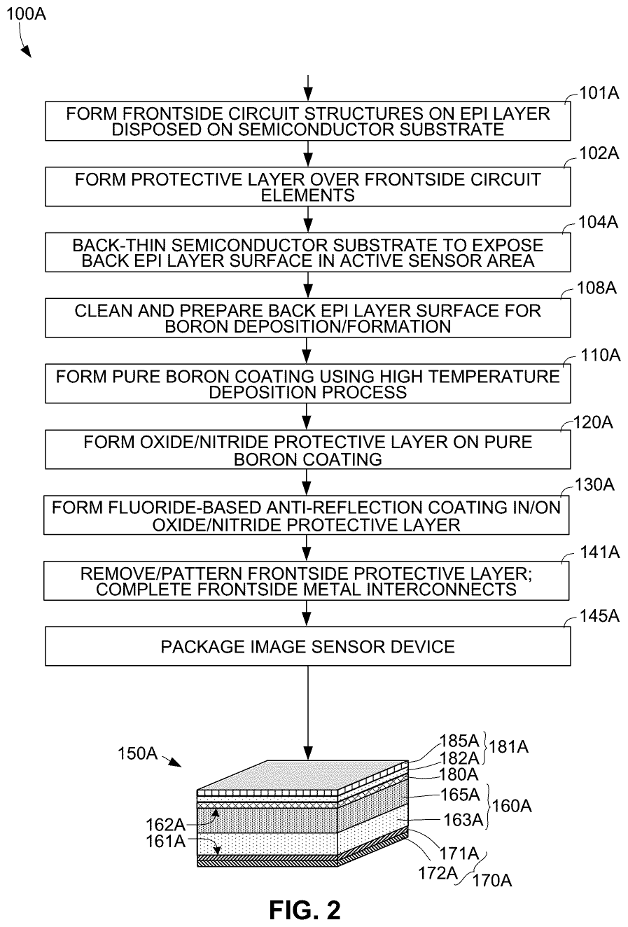

FIG. 1 is a flow diagram depicting a method 100 for producing an image sensor 150 that is configured to sense DUV/VUV radiation according to a generalized embodiment of the present invention. Image sensor 150 is depicted in a simplified form at the bottom of FIG. 1 for reference. Additional details and options related to method 100 and image sensor 150 are described below with reference to FIGS. 2 through 8C.

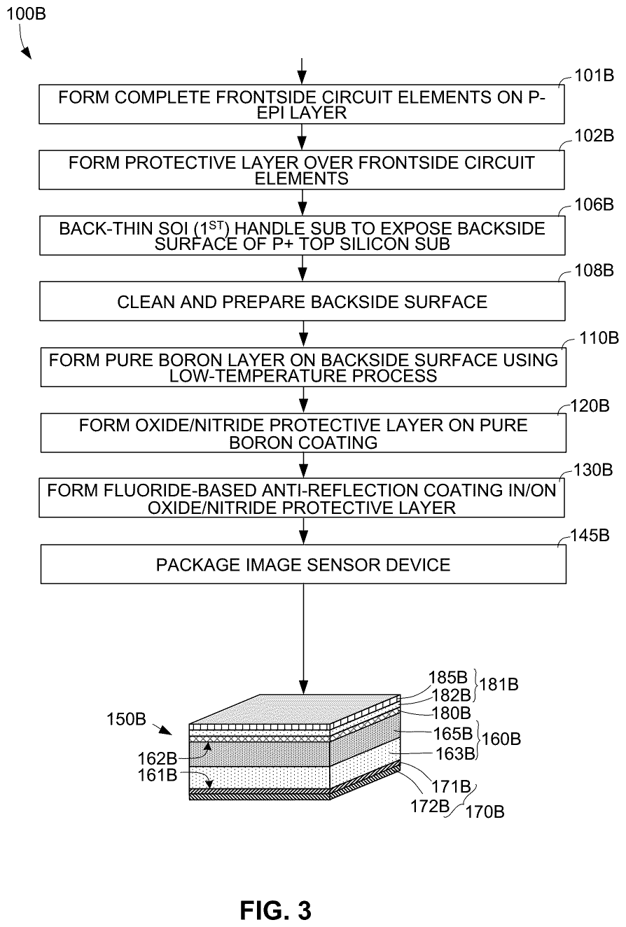

Referring to block 101 at the top of FIG. 1 and to image sensor 150 at the bottom of FIG. 1, front-end circuit structures 171 are generated on the frontside surface 161 of a semiconductor membrane 160 using well-known integrated circuit (IC) fabrication processes such as lithography, deposition, ion implantation, annealing and etching. As known in the art, these well-known IC fabrication processes typically include front-end processes during which non-metal structures are generated in and on a layer of semiconductor material (e.g., the surface of a silicon substrate or epitaxial silicon layer), and back-end processes that include the formation of metal interconnects and other back-end circuit structures. As used herein, the phrase “semiconductor membrane” refers to one or more semiconductor material layers (e.g., a monochrome silicon substrate and/or one or more stacked epitaxial silicon layers), and the phrase “front-end circuit structures” refers to the typically non-metal structures generated in and on the semiconductor membrane during the front-end portion of a typical IC fabrication process. In contrast, the phrase “frontside circuit elements” refers to completed circuit structures that collectively perform image sensor operations and include both front-end circuit structures and back-end circuit structures (e.g., metal interconnects and other structures formed during the back-end portion of a typical IC fabrication process). When completed, the frontside circuit elements include light sensitive devices such as charge coupled devices (CCDs), complementary metal oxide semiconductor (CMOS) imagers and photodiodes, and other semiconductor devices such as transistors, diodes, resistors and capacitors that are configured to collectively perform image sensor operations when image sensor 150 is implemented in an inspection system. As set forth in the specific embodiments described below with reference to FIGS. 2 and 3, in some cases only front-end circuit structures are generated during the process of block 101, and in other cases front-end circuit structures are generated along with back-end circuit structures to provide completed frontside circuit elements. Therefore, at least the front-end circuit structures of frontside circuit elements are formed during the process of block 101. After frontside processing is completed, membrane 160 is typically cleaned thoroughly using standard cleaning RCA 1 and RCA 2, along with a dilute HF or BHF dip to remove surface contaminants and surface oxide from the surface and ensure only silicon surface or hydrogenated silicon surface is exposed during the subsequent processing described below. An optional layer may be formed over front-end circuit structures 171 for protection during subsequent processing.

Next, a pure boron coating 180 is formed on backside (second) surface 162 of semiconductor membrane 160 at least in locations opposite to active sensor areas defined by the location of front-end circuit structures 171 (block 110). Pure boron coating 180 comprises a boron concentration of 80% or higher with inter-diffused silicon atoms and oxygen atoms predominantly making up the remaining 20% or less. In one embodiment, the formation of pure boron coating 180 involves depositing one or more amorphous layers of pure boron on exposed backside surface 162 until pure boron coating 180 has a total thickness T₁₈₀ in the range of 2 nm to 20 nm. In alternative embodiments, pure boron layer 180 may be formed using one of a physical vapor deposition (PVD) method such as thermal or ebeam evaporation; a chemical vapor deposition (CVD) method such as atmospheric (APCVD), plasma enhanced (PECVD), or low pressure (LPCVD); an atomic layer deposition (ALD) method, which can be thermal or plasma enhanced; or molecular beam epitaxy (MBE). In some embodiments, pure boron coating 180 is formed using a multi-cycle plasma ALD boron deposition process in which a plurality of plasma ALD cycles are performed to sequentially generate boron nanolayers that collectively form pure boron coating 180. This multi-cycle plasma ALD boron deposition process is described in co-owned and co-pending U.S. Published Patent Application No. 2022/0254829 entitled “Back Illuminated Sensor with Boron Layer Deposited Using Plasma Atomic Layer Deposition”, which is incorporated herein by reference.

A two-part anti-reflection coating 181 is then provided over pure boron coating 180 by forming a protective layer 182 on pure boron coating 180 (i.e., such that pure boron coating 180 is between protective layer 182 and semiconductor membrane 160; block 120), and then forming a fluoride-based anti-reflection (AR) coating 185 on protective layer 182 (i.e., such that protective layer 182 is between fluoride-based AR coating 185 and pure boron coating 180; block 130).

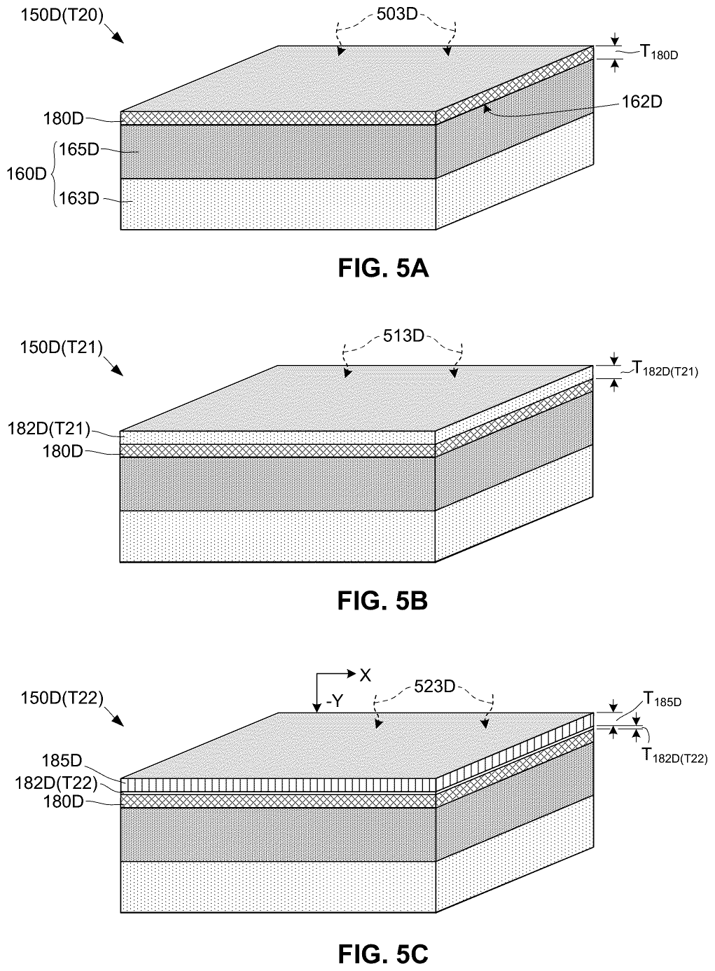

Referring to block 120, the formation of protective layer 182 involves forming one of an oxide film and a nitride film on pure boron coating 180, where the oxide/nitride film has a minimum thickness Tis: of about 0.5 nm (i.e., when properly fabricated, oxide/nitride films having this minimum thickness are able to substantially impede the migration of fluoride ions from the subsequently formed fluoride-based AR coating 185 to pure boron layer 180, thereby protecting pure boron coating 180 from the subsequently formed fluoride-based AR coating 185). In one embodiment, protective layer 182 is formed by depositing at least one of Al₂O₃, MgO, La₂O₃, Li₂O, CaO, BeO, HfO₂, AlN, Li₃N, LaN, Mg₃N₂, HfN and Ca₃N₂ on an upper surface 1800 of pure boron coating 180 using one of the PVD, CVD, ALD or MBE methods mentioned above. A final maximum thickness Tis of protective layer 182 is preferably limited to 10 nm or less to minimize the absorption of DUV/VUV radiation by the selected oxide/nitride material. In some embodiments, such when fluoride-based AR layer 185 is formed using the fluorination process described below with reference to FIGS. 5A to 5C, protective layer 182 may be formed with an initial thickness of up to 50 nm, provided the fluorination process converts a sufficient amount of the oxide/nitride film to produce a final protection layer thickness T₁₈₂ preferably in the range of 0.5 nm and 10 nm. In some higher wavelength DUV applications (e.g., above 170 nm), absorption by the oxide/nitride material may be negligible, allowing for thicknesses of up to 50 nm. That is, when two-part anti-reflective coating 181 is designed for DUV or the long wavelength end of VUV (for example wavelengths in a range from about 170 nm to about 250 nm), the optical properties of a thicker oxide/nitride protective layer 182 (e.g., up to 50 nm) may be utilized to further reduce the reflectivity (i.e., in combination with fluoride-based anti-reflective coating 185).

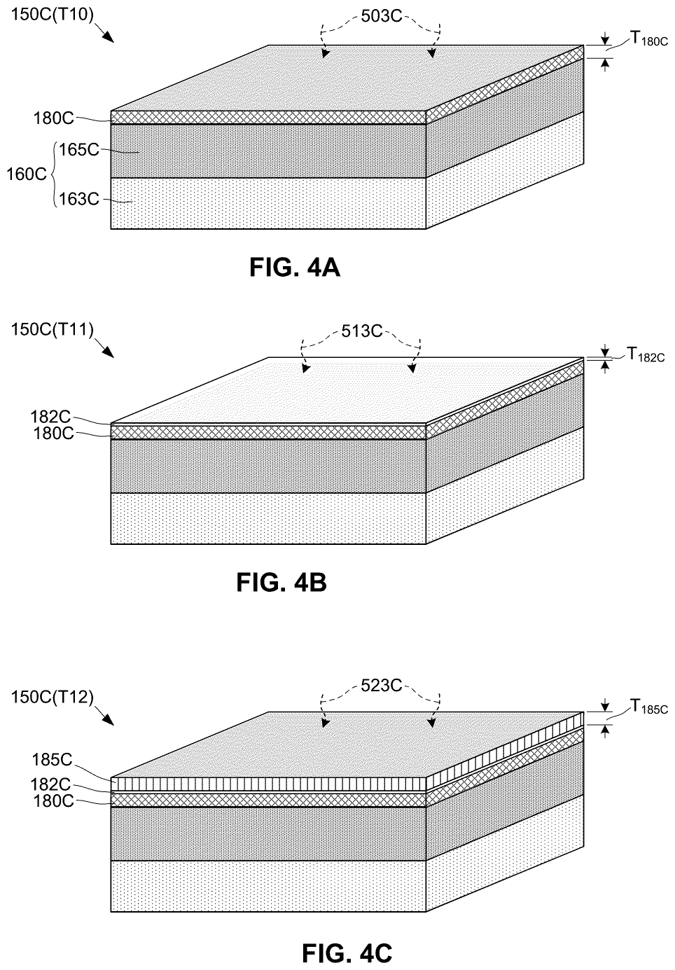

Referring to block 130, in alternative exemplary embodiments the formation of fluoride-based AR coating 185 involves either depositing a fluoride-based material or converting oxide/nitride material into a fluoride-based material using a fluorine-containing gas. In some embodiments (e.g., as described below with reference to FIGS. 4A to 4C), fluoride-based AR coating 185 is formed by depositing a selected fluoride-based material (e.g., at least one of AlF₃, MgF₂, CaF₂, LaF₃, LiF, and HfF₄) onto protection layer 182. In other embodiments (e.g., as described below with reference to FIGS. 5A to 5C), the fluoride-based material is formed by converting an upper region portion of oxide/nitride material forming protection layer 182 into fluoride using a fluorination process (e.g., by exposing the oxide/nitride material to one or more fluorine-containing gases such as F₂, HF, XeF₂, CH₃F, SF₆, CF₄, NbF₅, or Wf₆). In either case, fluoride-based AR coating 185 is formed such that its final thickness T₁₈₅ minimizes reflections from image sensor 150 at the DUV/VUV wavelengths of interest (e.g., in the range of 2 nm and 40 nm).

After completing the formation of pure boron coating 180 and two-part anti-reflection coating 181, additional processing (block 140) is performed to complete the fabrication and packaging of image sensor 150. For example, as indicated by image sensor 150A, which is shown at the bottom of FIG. 2, in some embodiments the additional processing may include completing the fabrication of front-end circuit elements 170A by forming back-end interconnects 172A on front-end circuit structures 171A. FIGS. 2 and 3 include flow diagrams showing the image sensor fabrication method 100 (FIG. 1) in additional detail, where FIG. 2 depicts a first alternative method 100A utilizing a high-temperature boron formation process, and FIG. 3 depicts a method 100B utilizing a low-temperature boron formation process. Note that similar reference numbers are utilized to indicate similar processes and features in these figures, and the suffixes “A” and “B” are appended to the end of the reference numbers to identify the specific process/feature under consideration. A similar numbering approach is utilized in the additional embodiments described below with reference to FIGS. 4A to 8.

Referring to the top of FIG. 2, method 100A generally begins by forming frontside circuit structures 171A on frontside surface 161A of semiconductor membrane 160A using standard semiconductor processing steps including lithography, deposition, ion implantation, annealing, and etching. Referring to image sensor 150A, semiconductor membrane 160A includes a silicon epitaxial (epi) layer 163A and a monocrystalline or polycrystalline silicon substrate 165A, where a downward facing surface of epi layer 163A defines frontside surface 161A of semiconductor membrane 160A, and an upward facing surface of substrate 165A defines a backside surface 162A of membrane 160B. In alternative embodiments, frontside circuit structures 171A are configured to implement either CCD or CMOS sensor elements and devices. In one embodiment epi layer 163A has a thickness of about 10 μm to 40 μm. In preferred embodiments, both epi layer 163A and substrate 165A are doped with p-type dopants (e.g., boron), with epi layer 163A having a much lower dopant concentration than substrate 165A (e.g., such that epi layer 163A has a resistivity in the range of 10 to 2000 Ωcm, and substrate 165A has a resistivity less than about 1 Ωcm). Note that only frontside circuit structures 171A (e.g., poly-silicon interconnects) are formed at this stage, and that metal interconnects 172A needed to complete front-end circuit elements 170A are not formed at this time because metals will be damaged in subsequent high-temperature processing steps.

A protective layer is then formed over the frontside surface 161A (block 102A). In one embodiment the protective layer (not shown) may be formed by depositing one or more protective materials on top of frontside circuit structures 171A. The one or more protective materials may comprise silicon dioxide, silicon nitride or other material.

In some embodiments, the wafer including membrane 160A is thinned from the backside to expose epitaxial layer 163A in, at least, the active sensor areas (block 104A). This step may involve polishing, etching, or both. In some embodiments, the entire wafer is back-thinned using known techniques. In other embodiments, only the active sensor areas are thinned all the way to the epitaxial layer.

Next, the backside surface is cleaned and prepared for boron deposition/formation (block 108A). During this cleaning process, the native oxide, and any contaminants, including organics and metals, should be removed from the exposed backside surface (i.e., the surface exposed during the thinning process of block 104A). In one embodiment, this cleaning can be performed using a dilute HF solution or using an RCA cleaning process. After cleaning, the wafer can be dried using the Marangoni drying technique or a similar technique to leave the surface dry and free of water marks. In preferred embodiments, the wafer is protected in a controlled environment during the thinning and cleaning/preparing processes (e.g. in a vacuum environment or in an environment purged with a dry, inert gas such as nitrogen) to minimize native oxide regrowth after the cleaning.

An amorphous layer of pure boron is then deposited on the exposed backside surface using a high-temperature boron deposition process (block 110A). In one preferred embodiment, this deposition can be performed using a mixture of diborane and hydrogen gases at a temperature of about 700-800° ° C. to create a high-purity amorphous boron layer. In preferred embodiments, the thickness of the amorphous boron layer is between 2-20 nm. The minimum thinness is generally limited by the compromise between the need for a pinhole-free uniform film and the absorption of the photons of interest by the boron. In preferred embodiments, prior to the boron deposition, the wafer can be held at a high temperature for a few minutes in a reducing environment, such as a dilute hydrogen gas or a low-pressure hydrogen gas, to remove any native oxide layer that might have regrown after the back-thinning process while the wafer is maintained in the same chamber used for boron deposition. In preferred embodiments, the temperature is approximately 800° C. for less than 5 minutes, and the boron deposition process is performed immediately in the same chamber.

A two-part AR coating 181A is then formed over pure boron coating 180A using any of the processes described above with reference to blocks 120 and 130 (FIG. 1). Namely, an oxide/nitride protective layer 182A is formed on pure boron coating 180A (block 120A), and then a fluoride-based AR coating 185A is formed in or on protective layer 182A (block 130A).

Next, processes associated with the completion of image sensors 150 are performed (block 141A). In one embodiment, these processes include removal or patterning of the front-side protective layer to facilitate the fabrication of metallic interconnects 172A on frontside circuit structures 171A. In some embodiments, this removal/patterning may include various wet and dry etching processes and photolithographic patterning steps. Metallic interconnects 172A may be formed using one or more of Al, Cu, or another metal. After interconnect fabrication is complete, a passivation layer may be deposited on the frontside surface to protect completed image sensors 150A.

In some embodiments, the protective layer formation process (block 120A) and completion of the image sensors (block 141A) may be performed in the order indicated in FIG. 2 after the fluoride-based AR coating formation process (block 130A). In alternative embodiments, the protective layer formation process (block 120A) and fluoride-based AR coating formation process (block 130A) after completion of the image sensors (block 141A). In other alternative embodiments, completion of the image sensors (block 141A) may be performed after the protective layer formation process (block 120A), and then the fluoride-based AR coating formation process (block 130A) performed after completion of the image sensors (block 141A).

After completing front-end circuit elements 170A, image sensor 150A is packaged. This packaging process may include flip-chip bonding or wire bonding of a chip to a substrate. The package may include a window that transmits wavelengths of interest or may comprise a flange or seal for interface to a vacuum seal.

FIG. 3 illustrates a method 100B for producing an image sensor 150B (see bottom of FIG. 3) on a semiconductor membrane 160B using a low-temperature (i.e., at or below 450° C.) boron layer formation process according to another embodiment. Referring to image sensor 150B, semiconductor membrane 160B includes an lightly-doped epi layer 163B defining a frontside surface 161B and a highly p-doped epi layer 165B defining a backside surface 162B. Other structural features and resistivity of membrane 160B are similar to those described above with reference to membrane 160A (FIG. 2).

Next, as indicated in block 101B, complete front-end circuit elements 170B (i.e., both front-end circuit structures 171B and metal interconnects 172B) are generated on frontside surface 161B of p− epi layer 163B using standard semiconductor processing steps such as lithography, deposition, ion implantation, annealing, and etching. Charge-coupled device (CCD) and/or CMOS sensor elements and devices may also be created during the fabrication of front-end circuit elements 170B. Note that both frontside circuit structures 171A (e.g., poly-silicon interconnects) and metal interconnects 172A may be formed at this time because the subsequent low-temperature processing will not damage the metal interconnects.

In some embodiments one or more protective layers (e.g., silicon dioxide, silicon nitride or other material) are then deposited on front-end circuit elements 170B (block 102B). This protection may include attaching the wafer including membrane 160B to a handling wafer (not shown), such as a silicon wafer, a quartz wafer, or a wafer made of other material. The handling wafer may include through-wafer vias for connecting to the circuit elements.

Next, the wafer is thinned from the backside to expose the epitaxial layer in, at least, the active sensor areas. This process may involve polishing, etching, or both. In some embodiments, the entire wafer is back-thinned. In other embodiments, only the active sensor areas are thinned all the way to the epitaxial layer.

Next, membrane 160B is cleaned and prepared for the formation of pure boron coating 180B. During this cleaning/preparing process, the native oxide, and any contaminants, including organics and metals, should be removed from the backside surface. In one embodiment, this cleaning can be performed using a dilute HF solution or using an RCA clean process. After cleaning, the wafer can be dried using the Marangoni drying technique or a similar technique to leave the surface dry and free of water marks. In preferred embodiments, the wafer is protected in a controlled environment (e.g. in a vacuum environment or in an environment purged with a dry, inert gas such as nitrogen) during the back-thinning and cleaning/preparing processes to minimize native oxide regrowth after the cleaning.

pure boron coating 180B is then formed by depositing an amorphous layer of pure boron on the exposed backside surface using a low-temperature boron deposition process (block 110B). In some embodiments, p+ (second) epi layer 165B is formed on p− epi layer 163B by growing epitaxial silicon on the exposed backside surface using a low-temperature epitaxial growth process while doping the second epitaxial silicon layer with boron during the epitaxial growth process. The amorphous layer of pure boron is then deposited over second epitaxial layer 165B. In preferred embodiments, second epitaxial silicon layer 165B and the amorphous boron layer are deposited at or below 450° C. so that the metal contacts on the front side are not damaged. In preferred embodiments, the thicknesses of the second boron doped epitaxial layer and amorphous boron layer are in the range of 2-20 nm.

A two-part AR coating 181B is then formed over pure boron coating 180B using any of the processes described above with reference to blocks 120 and 130 (FIG. 1). Namely, an oxide/nitride protective layer 182B is formed on pure boron coating 180B (block 120B), and then a fluoride-based AR coating 185B is formed in or on protective layer 182B (block 130B). After two-part AR coating 181B is formed as described above, the frontside protective layer is removed, the wafer is diced and the separate image sensors 150B are then packaged for operation using known techniques (block 145B). The package may include flip-chip bonding or wire bonding of a chip to a substrate. The package may include a window that transmits wavelengths of interest or may comprise a flange or seal for interface to a vacuum seal or a seal for a purge gas.

FIGS. 4A to 4C depict relevant fabrication stages associated with the generation of an image sensor 150C in which a fluoride-based AR coating 185C is formed by depositing one or more boron material layers over an oxide/nitride protection layer 182C. The layer thicknesses depicted in FIGS. 4A-4C are not to scale and are only provided for illustration purpose. In these figures the interfaces are depicted as being flat for explaining the relevant concepts, but in a sensor the Si surface can be rough, in nm to microns scale, and the oxide or nitride protection layer and fluoride-based AR layer can be deposited in a similar manner. It is also possible that in some embodiments represented by 4B, the interface of the protection layer and fluoride layer may have a few layers of mixed oxy-fluoride or nitro-fluorides type compounds due to intermixing of the oxide or nitride and fluoride layers during the fluoride deposition process.

FIG. 4A depicts image sensor 150C at a time T10 after a pure boron coating 180C has been formed over backside (second) surface 162C of membrane 160C, which includes very lightly p-doped bulk epitaxial silicon layer 163C and a heavily p-doped layer 165C. In some embodiments, silicon layer 165C is formed after the boron deposition by way of an anneal step that causes boron atoms to heavily p-doped a portion of epitaxial silicon located adjacent to backside surface 162C. In another embodiment, silicon layer 165C represents a low temperature heavily p-doped epitaxial silicon layer that is grown prior to formation of pure boron coating 180C using a low temperature boron deposition process. The heavily p-doped material forming silicon layer 165C may be crystalline or polycrystalline and may have a thickness in the range of a few nms to approximately 100 nm. The boron material 503C used to form pure boron layer 180C may deposited using a high temperature process (e.g., greater than 450° C.) or a low temperature process (e.g., less than or equal to 450° C.), and may comprise one or more amorphous boron layers having a total thickness T_{180C} in the range of 2 nm to 20 nm.

FIG. 4B depicts image sensor 150C at a time T11 after an oxide and/or nitride material 513C have been deposited on pure boron layer 185C to form a protective layer 182C. In some embodiments, oxide/nitride protective layer 182C is formed by forming a thin film comprising one or more of Al₂O₃, MgO, La₂O₃, Li₂O, CaO, BeO, HfO₂, AlN, Li₃N, LaN, Mg₃N₂, HfN and Ca₃N₂. In some embodiments the oxide/nitride thin film is formed using one of various deposition methods including but not limited to physical vapor deposition (PVD) methods such as thermal or ebeam evaporation; chemical vapor deposition (CVD) methods such as atmospheric (APCVD), plasma enhanced (PECVD), or low pressure (LPCVD); atomic layer deposition (ALD) which can also be thermal, or plasma enhanced; or molecular beam epitaxy (MBE). In the present embodiment protection layer 182C is formed with a total thickness T_{182C(T11)} in the range of 2 nm to 10 nm. In preferred embodiments, protective layer 182D is formed by depositing Al₂O₃ using an ALD process due to the required atomic level control of oxide thickness. As mentioned above, oxide/nitride protection layer 183C serves to protect pure boron coating 180C during the subsequent fluoride antireflection coating process, thereby preventing boron loss and pin hole formation.

FIG. 4C depicts image sensor 150C at a time T12 after a fluoride material 513C has been deposited in a way that generates a fluoride-based AR layer 185C over oxide/nitride protection layer 182C. In some embodiments, the fluoride deposition process is performed using one or more of AlF₃, MgF₂, LaF₂, LiF, or CaF₂ and one of various deposition methods including but not limited to methods such as physical vapor deposition (PVD) methods such as thermal or ebeam evaporation; chemical vapor deposition (CVD) methods such as atmospheric (APCVD), plasma enhanced (PECVD), or low pressure (LPCVD); atomic layer deposition (ALD) which can also be thermal or plasma enhanced; or molecular beam epitaxy (MBE). In preferred embodiments, fluoride-based layers are deposited via atomic layer deposition or ion beam sputtering deposition at temperatures at or below 450° C. The fluorination process is performed until a total thickness Ties of the resulting fluoride-based AR coating 185C corresponds to the reflection minimization thickness for the DUV/VUV wavelengths of interest.

FIGS. 5A-5C depict relevant fabrication stages associated with the generation of an image sensor 150D that utilizes a fluorination process to generate a fluoride-based AR coating 185D by converting an upper region of a protection layer 182D. The layer thicknesses depicted in FIGS. 5A-5C are not to scale and are only provided for illustration purpose. In these figures the interfaces are depicted as being flat for explaining the relevant concepts, but in a sensor the Si surface can be rough, in nm to microns scale, and the oxide or nitride protection layer and fluoride-based AR layer can be deposited in a similar manner. It is also possible that in some embodiments represented by 5B, the interface of the protection layer and fluoride layer may have a few layers of mixed oxy-fluoride or nitro-fluorides type compounds due to intermixing of the oxide or nitride and fluoride layers during the fluorination process.

FIG. 5A depicts image sensor 150D at a time T20 after a pure boron coating 180D has been formed over backside (second) surface 162D of membrane 160D, which includes very lightly p-doped bulk epitaxial silicon layer 163D and a heavily p-doped layer 165D. In some embodiments, silicon layer 165D is formed after the boron deposition by way of an anneal step that causes boron atoms to heavily p-doped a portion of epitaxial silicon located adjacent to backside surface 162D. In another embodiment, silicon layer 165D represents a low temperature heavily p-doped epitaxial silicon layer that is grown prior to formation of pure boron coating 180D using a low temperature boron deposition process. The heavily p-doped material forming silicon layer 165D may be crystalline or polycrystalline and may have a thickness in the range of a few nms to approximately 100 nm. The boron material 503D used to form pure boron layer 180D may deposited using a high temperature process (e.g., greater than 450° C.) or a low temperature process (e.g., less than or equal to 450° C.), and may comprise one or more amorphous boron layers having a total thickness T_{180D} in the range of 2 nm to 20 nm.

FIG. 5B depicts image sensor 150D at a time T₂₁ after an oxide and/or nitride material 513D have been deposited on pure boron layer 185D to form a protective layer 182D. In some embodiments, oxide/nitride protective layer 182D is formed by forming a thin film comprising one or more of Al₂O₃, MgO, La₂O₃, Li₂O, CaO, BeO, HfO₂, AlN, Li₃N, LaN, Mg₃N₂, HAN and Ca₃N₂. In some embodiments the oxide/nitride thin film is formed using one of various deposition methods including but not limited to physical vapor deposition (PVD) methods such as thermal or ebeam evaporation; chemical vapor deposition (CVD) methods such as atmospheric (APCVD), plasma enhanced (PECVD), or low pressure (LPCVD); atomic layer deposition (ALD) which can also be thermal or plasma enhanced; or molecular beam epitaxy (MBE). In the present embodiment, because an upper region of the oxide/nitride thin film will be converted by way of a fluorination process (e.g., as described below with reference to FIG. 5C), protection layer 182C is formed with a total thickness T_{182C(T21)} in the range of 10 nm to 50 nm (i.e., to assure that a suitably thick oxide/nitride layer will be retained after the fluorination process is completed). In preferred embodiments, protective layer 182D is formed by depositing Al₂O₃ using an ALD process due to the required atomic level control of oxide thickness.

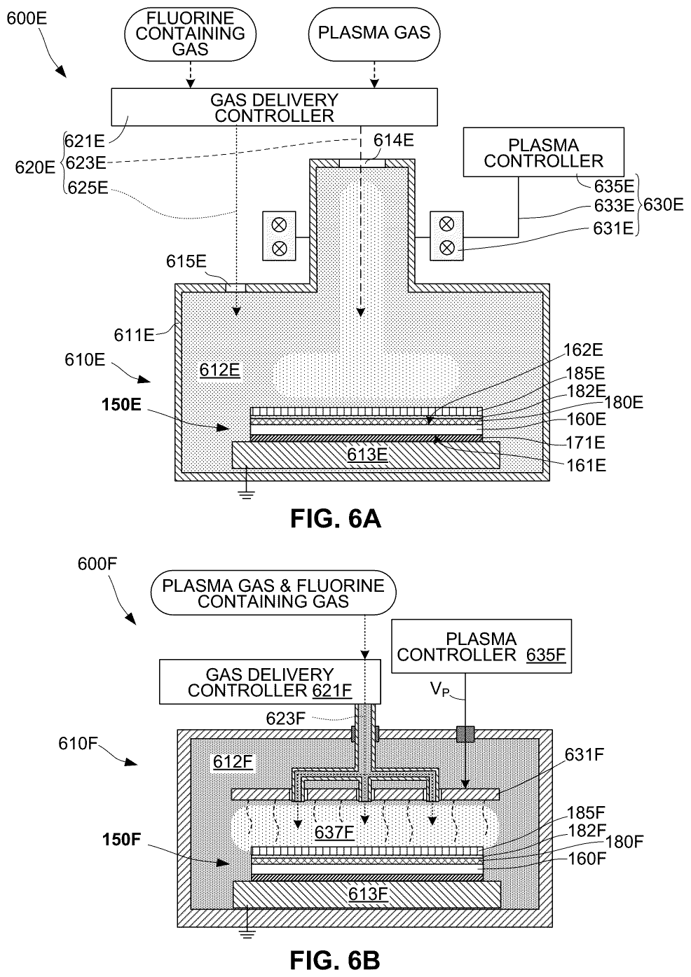

FIG. 5C depicts image sensor 150D at a time T22 after a fluorination process has been utilized to convert an upper region of the protection layer 182D into a fluoride-based AR coating layer 185D. In some embodiments, the fluorination process is achieved by exposing the oxide/nitride material forming protection layer 182D to fluorine-containing gases 523D such as F₂, HE, XeF₂, CH₃F, SF₆, CF₄, NbF₅, or Wf₆. In some embodiments, the fluorine-containing gases may be mixed with other gases such as O₂, Ar and N₂ to enhance the fluorination process. In some embodiments, the fluorination process may include a plasma process, such as those described below with reference to FIGS. 6A and 6B, to generate fluorine-containing plasmas in order to expedite the reaction at comparatively lower temperatures than the cases without plasma. In all cases the exposure of protection layer 182F to gases 523D causes a substantially uniform top-down diffusion/migration of fluoride into the oxide/nitride material (i.e., such that the fluorination process gradually proceeds in the −Y axis direction, whereby an upper region of protection layer 182F is converted from oxide/nitride to fluoride-based material). The time and temperature for the fluorination process are chosen such that the thermal budget for the behavior of the image sensor circuit components does not deviate from the expected behavior beyond a tolerance limit decided by the application. For example, when method 100B (FIG. 3) is utilized, because the fluorination process is implemented after front end metallization, the maximum temperature utilized during the fluorination process is preferably equal to or less than 450° C. Typical temperatures for performing the fluorination process are less than 500° C. The time duration of the fluorination process is determined by various factors such as the selected process conditions, the rate at which the selected oxide/nitride material converts to fluoride, the targeted thickness T_{185D} of the resulting fluoride-based AR coating 185D, and a targeted final thickness T_{182D(T22)} of the oxide/nitride layer forming protection layer 182D. The targeted thickness T_{185D} of the resulting fluoride-based AR coating 185D is preferably selected to correspond with a reflection minimization thickness for the DUV/VUV wavelengths of interest.

FIGS. 6A and 6B show exemplary deposition systems 600E and 600F, respectively, which may be utilized to perform the fluorination process described above with reference to FIG. 5C using a plasma process. Exemplary systems 600E and 600F are greatly simplified and provided solely for descriptive purposes, and features mentioned below are not intended to be limiting unless specifically referenced in the claims. That is, those skilled in the art will recognize that plasma-capable deposition chambers suitable for performing the fluorination process may include features other than those depicted in FIGS. 6A and 6B.

Referring to FIG. 6A, system 600E includes a plasma-capable deposition chamber 610E, a gas flow system 620E and a plasma generating system 630E. Deposition chamber 610E includes a chamber wall 611E surrounding a processing region 612E. Gas flow system 620E includes a gas delivery controller 621E configured to control the flow of plasma gas and fluorine containing gas into processing region 612E. Plasma generating system 630E includes a plasma generator 631E connected by way of a conductor 633E to a plasma controller 635E. To perform the fluorination process, partially formed image sensor 150E is disposed in deposition chamber 610E with membrane 160E mounted on a stage (support structure) 613E with first surface 161E facing downward (i.e., such that circuit structures 171E are disposed between membrane 160E and stage 613E), and with second surface 162E facing upward toward plasma generator 631E. In some embodiments pure boron coating 180E and oxide/nitride protection layer 182E have been previously formed over second surface 162E before membrane 160E is placed on stage 613E. In other embodiments, membrane 160E is placed on stage 613 after circuit structures 171E are fabricated, and system 600E may be utilized to perform cleaning and the formation of pure boron coating 180E and protective layer 182E before beginning the fluorination process. The fluorination process begins by utilizing gas delivery system 620E to generate a gas flow 623E through a gas entrance 614E (indicated by dashed-line arrow) and utilizing plasma generating system 630E to generate a plasma over protective layer 182E using plasma gasses included in gas flow 623E. In some embodiments, gas flow 623E also includes fluorine-containing gases, and in other embodiments the fluorine-containing gases may also be introduced into processing region 612E using the optional gas entrance 615E to facilitate optimizing the fluorination recipe. In some embodiments, stage 613E rotates under the resulting plasma, and is grounded or biased to some voltage to adjust the plasma fluorination recipe. The plasma and gas flow are maintained until a sufficient amount of the oxide/nitride material forming protective layer 182E is fluorinated (converted into fluoride-based AR coating 185E), but the fluorination process is terminated before protective layer 182E is entirely consumed (i.e., such that a suitably thick oxide/nitride protection layer 182E separates pure boron layer 180E from fluoride-based AR coating 185E after the fluorination process is completed).

FIG. 6B shows a second exemplary chamber 600F including a plasma-capable deposition chamber 610F surrounding a processing region 612E, which contains a stage (substrate holder) 613F on which partially formed image sensor 150F is placed in the manner described above. To perform the fluorination process, a gas delivery controller 621E controls the flow of plasma gas and fluorine containing gas into processing region 612E and through one or more apertures formed in an electrode 631F, and plasma controller 635F biases electrode 631F (e.g., using a plasma voltage V_{P}) with respect to stage 613F, which acts as a 2^{nd} electrode, to generate a capacitively coupled plasm 637F over membrane 160F. In some embodiments, stage 613F rotates membrane 160F under plasma 637F, and/or the fluorine-containing gases could be mixed with Ar, O₂ and N₂ for plasma generation and/or fluorination process purposes. The plasma and gas flow are maintained until a suitably thick fluoride-based AR coating 185F is formed that is separated from pure boron layer 180F by a thin oxide/nitride protection layer 182F.

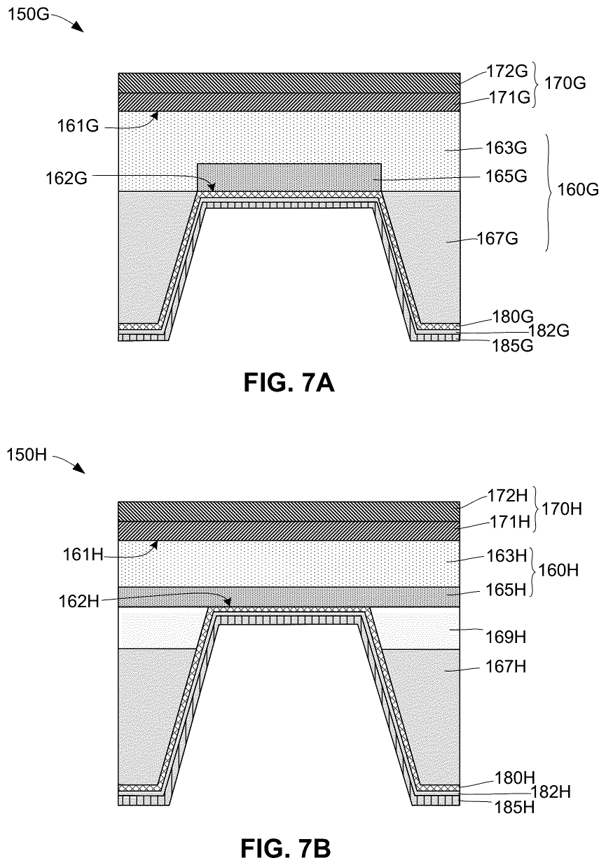

FIGS. 7A and 7B show cross section schematics of partially back-thinned image sensors 150G and 150H that are fabricated according to additional alternative embodiments.

Referring to FIG. 7A, image sensor 150G is fabricated on a membrane 160G including a lightly p-doped (p−) epitaxial silicon layer 163G formed directly on a monocrystalline or polycrystalline silicon substrate 167G. Front-end circuit structures 171G are fabricated on a frontside surface 161G of epitaxial layer 163G and then covered by a protective layer (not shown). Portions of silicon substrate 167G located over active sensor areas are then back-thinned to expose a portion of the p-doped epitaxial silicon layer 163G, where said exposed portion of the p-doped epitaxial silicon layer 163G forms backside (second) surface 162G of semiconductor membrane 160G. Pure boron coating 180G is then formed on backside surface 162G, then oxide/nitride protective layer 182G is formed over pure boron coating 180C, and then a high temperature drive-in process is performed to generate highly boron doped (p+) backside (second) epitaxial region 165G to provide high back surface conductivity. Metal interconnects 172G are then formed on front-end circuit structures 171G to complete front-end circuit elements 170G, and a fluoride-based anti-reflection coating 185G is then formed on oxide/nitride protective layer 182G to reduce the reflection and thus enhance the quantum efficiency of image sensor 150G for DUV and VUV wavelengths. Additional details related to the formation of image sensor 150G are described in Chern et al., “Back-Illuminated Sensor With Boron Coating, U.S. Pat. No. 9,496,425, which is incorporated herein by reference.

Referring to FIG. 7B, image sensor 150H is fabricated on a silicon-on-insulator (SOI) structure using a low-temperature fabrication method. Because low-temperature processing is used during subsequent processing, complete front-end circuit elements 170H (i.e., both front-end circuit structures 171H and metal interconnects 172H) are formed on frontside surface 161H of a lightly p-doped epitaxial layer 163H that is grown on the SOI's thin top silicon substrate 165H. Note that top silicon substrate 165HD is highly boron-doped for high back surface conductivity prior to growing p− epitaxial layer 163H. Partial back-thinning of the SOI's handle substrate 167H and oxide layer 169H is then performed to expose portions of backside surface 162H of top silicon substrate 165H. Pure boron coating 180H is then formed on exposed backside surface 162H using a low temperature (<450° C.) plasma ALD boron coating formation process for long exposure lifetime, then an oxide/nitride protection layer 182J is formed on pure boron coating 180D, and then a fluoride-based antireflection coating 185D is formed for enhanced quantum efficiency. Sensor 150H primarily differs from sensor 150G (FIG. 7A) in that sensor 150H retains a portion of the original SOI structure's oxide layer 169H between the retained portion of handle silicon substrate 167H and p+ silicon substrate 165H. That is, p− epitaxial layer 163H and p+ silicon substrate 165H form an effective semiconductor membrane 160H of image sensor 150H, with retained oxide portions 169H and retained handle substrate portions 167H being attached to membrane 160H over non-active sensor areas. Additional details for producing sensor 150H are provided, for example, in “Back-Illuminated Sensor And A Method Of Manufacturing A Sensor Using A Silicon On Insulator Wafer”, Haddidi et al., U.S. Pat. No. 11,848,350, which is incorporated herein by reference in its entirety.

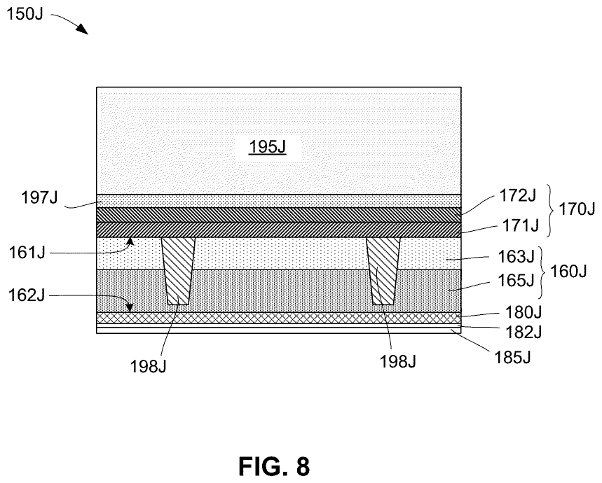

FIG. 8 shows another image sensor 150J having a pure plasma ALD boron coating 180J formed on an SOI substrate using a low-temperature fabrication method according to another specific embodiment. Like the example described above with reference to FIG. 7B, SOI top silicon substrate 165J is highly boron-doped for high back surface conductivity, and then a lightly p-doped epitaxial layer 163J is grown thereon. Complete front-end circuit elements 170J (i.e., both front-end circuit structures 171J and metal interconnects 172J) are formed on frontside surface 161J of epitaxial layer 163J. In this embodiment through-silicon vias 198J are formed in p+ layer top silicon substrate 165J and p− epi layer 163J to provide electrical connection between backside surface 162J and front-end circuit elements 170J. Next, a full wafer thinning process is performed to remove the entire SOI handle substrate and oxide layer (not shown), whereby semiconductor membrane 160J of image sensor 150J is formed by p− epitaxial layer 163J and p+ silicon substrate 165J. Because image sensor 150J is fabricated utilizing full wafer thinning, the method includes bonding a handle substrate 195J to the front side surface after fabrication of front-end circuit elements 170J and after forming a protective layer 197J over circuit elements 170J. Handle substrate 195J and protective layer 197J are removed after backside processing is completed, which includes forming pure boron coating 180J on highly p-doped epitaxial layer 163J using the low temperature (<450° C.) plasma ALD boron layer formation process, then forming oxide/nitride protective layer 182J over pure boron coating 180E, and then forming a fluoride-based anti-reflection coating layer 185J for long term stability and higher quantum efficiency in DUV and VUV wavelengths. In some embodiments, portions of pure boron coating 180J and highly doped epitaxial layer 163J are etched/removed to expose lower ends of through-silicon vias 198J to facilitate frontside/backside connections. Additional fabrication procedure details used to form image sensor 150J on an SOI substrate are described, for example, in U.S. Pat. No. 11,848,350 cited above. Alternatively, sensor 150J can be formed on a silicon substrate using details provided, for example, in U.S. Pat. No. 9,496,425 cited above.

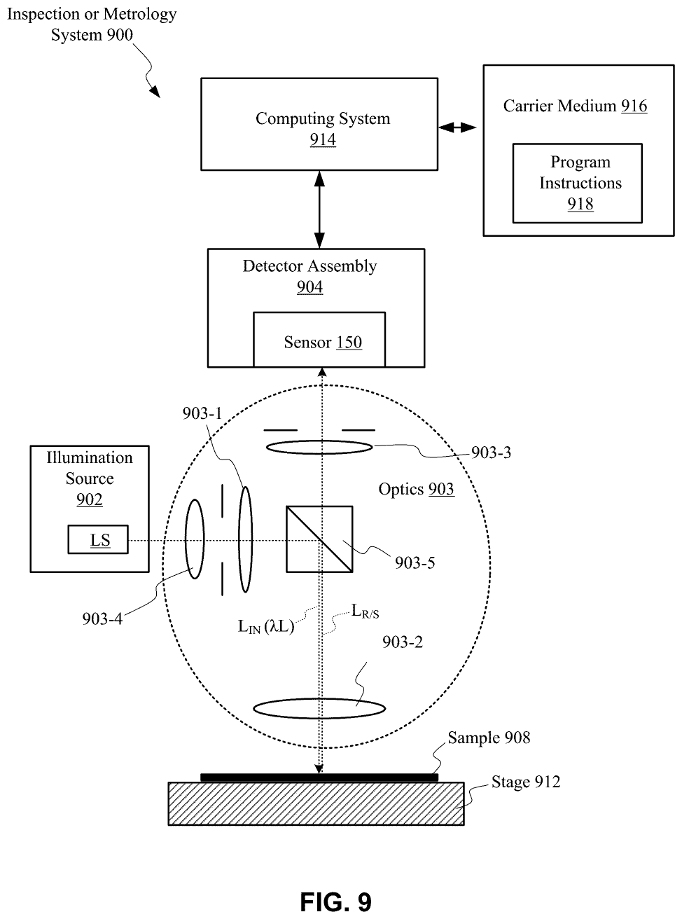

FIG. 9 illustrates an exemplary inspection or metrology system 900 configured to inspect or measure a semiconductor-fabrication-related sample 908, such as a silicon wafer, a reticle, or photomask, using an image sensor 150 configured in accordance with the present invention. System 900 generally includes an illumination (light) source 902, a detector assembly 904 and a stage 912.

Illumination source 902 is preferably configured to generate (emit) deep UV (DUV) and/or vacuum UV (VUV) incident light (radiation) L_{IN} having a wavelength in the range of 100 nm to 300 nm but may be configured to generate light having wavelengths below 100 nm (e.g., 13.5 nm for future EUV lithography) or greater than 300 nm. In some embodiments illumination source 902 utilizes one or more light sources LS and one or more optical components (e.g., a frequency converter) to generate incident light L_{IN}. In one embodiment, illumination source 902 may include a continuous light source, such as an arc lamp, a laser-pumped plasma light source, or a continuous wave (CW) laser. In another embodiment, illumination source 902 may include pulsed light source, such as a mode-locked laser, a Q-switched laser, or a plasma light source pumped by a mode-locked or Q-switched laser. Suitable light sources that may be included in illumination source 902 are described in U.S. Pat. No. 7,705,331, entitled “Methods and systems for providing illumination of a specimen for a process performed on the specimen”, to Kirk et al., U.S. Pat. No. 9,723,703, entitled “System and method for transverse pumping of laser-sustained plasma”, to Bezel et al., and U.S. Pat. No. 9,865,447, entitled “High brightness laser-sustained plasma broadband source”, to Chuang et al. These patents are incorporated by reference herein.

Stage 912 is configured to receive sample 908 and to facilitate movement of sample 908 relative to optical system 903 (i.e., such that optical system 903 focuses incident light L_{IN} on different regions of sample 908 and directs reflected/scattered light from the different regions to detector assembly 904). Stage 912 may comprise an X-Y stage or an R-θ stage. In one embodiment, stage 912 can adjust the height of sample 908 during inspection to maintain focus. In another embodiment, optics 903 can be adjusted to maintain focus.

Optical system (optics) 903 comprises multiple optical components and other optical components that are configured to direct and focus incident light L_{IN} onto sample 908, and to direct reflected (including scattered) light L_{R/S} from the sample 908 to detector assembly 904. The exemplary optical components of optical system 903 illustrated in FIG. 9 includes an illumination tube lens 903-1, an objective lens 903-2, a collection tube lens 903-3, a condensing lens 903-4 and a beam splitter 903-5. During the operation of system 900 incident light L_{IN} leaving illumination source 902 is directed by condensing lens 903-4 and illumination tube lens 903-1 to beam splitter 903-5, which directs incident light L_{IN} downward through objective lens 903-2 onto sample 908. Reflected/scattered light L_{R/S} represents the portion of incident light L_{IN} that is reflected and/or scattered in an upward direction into objective lens 903-2 by the surface features of sample 908 and is directed by objective lens 903-2 and collection tube lens 903-3 to detector assembly 904.

Detector assembly 904 includes one or more of image sensor 150 that is fabricated using any of the methods described herein. In alternative embodiments, sensor 150 includes a back-illuminated CCD sensor, a back-illuminated CMOS sensor, and electron-bombarded image sensor incorporating a Back-thinned solid-state image sensor. Image sensor 150 may comprise a two-dimensional array sensor or a one-dimensional line sensor. In one embodiment, the output of detector assembly 904 is provided to a computing system 914, which analyzes the output. Computing system 914 can be configured by program instructions 918, which can be stored on a carrier medium 916. In some embodiments of inspection system 900 incorporating a Q-switched laser, image sensor 150 or sensors 150 within detector assembly 904 are synchronized with the laser pulses. In such embodiments, image sensor 150 may operate in a TDI mode during the laser pulse and then may readout the data through multiple outputs on both sides of the sensor in between laser pulses. Some embodiments of inspection system illuminate a line on sample and collect scattered and/or reflected light in one or more dark-field and/or bright-field collection channels. In such embodiments, image sensor 150 may be a line sensor or an electron-bombarded line sensor. Some embodiments of inspection system illuminate multiple spots on sample and collect scattered and/or reflected light in one or more dark-field and/or brightfield collection channels. In such embodiments, image sensor 150 may be a two-dimensional array sensor or an electron bombarded two-dimensional array sensor.

Additional details of various embodiments of inspection or metrology system 900 are described in U.S. Pat. No. 9,891,177, entitled “TDI Sensor in a Darkfield System”, to Vazhaeparambil et al., U.S. Pat. No. 9,279,774, entitled “Wafer inspection”, to Romanovsky et al., U.S. Pat. No. 7,957,066, entitled “Split field inspection system using small catadioptric objectives”, to Armstrong et al., U.S. Pat. No. 7,817,260, entitled “Beam delivery system for laser dark-field illumination in a catadioptric optical system”, to Chuang et al., U.S. Pat. No. 5,999,310, entitled “Ultra-broadband UV microscope imaging system with wide range zoom capability”, to Shafer et al., U.S. Pat. No. 7,525,649, entitled “Surface inspection system using laser line illumination with two dimensional imaging”, to Leong et al., U.S. Pat. No. 9,080,971, entitled “Metrology systems and methods”, to Kandel et al., U.S. Pat. No. 7,474,461, entitled “Broad band objective having improved lateral color performance”, to Chuang et al., U.S. Pat. No. 9,470,639, entitled “Optical metrology with reduced sensitivity to grating anomalies”, to Zhuang et al., U.S. Pat. No. 9,228,943, entitled “Dynamically Adjustable Semiconductor Metrology System”, to Wang et al., U.S. Pat. No. 5,608,526, entitled “Focused Beam Spectroscopic Ellipsometry Method and System”, to Piwonka-Corle et al., issued on Mar. 4, 1997, and U.S. Pat. No. 6,297,880, entitled “Apparatus for Analyzing Multi-Layer Thin Film Stacks on Semiconductors”, to Rosencwaig et al., issued on Oct. 2, 2001. All of these patents are incorporated by reference herein.

The various embodiments of the structures and methods of this invention that are described above are illustrative only of the principles of this invention and are not intended to limit the scope of the invention to the embodiments described. For example, additional steps may be added, or order of the steps may be changed from what is depicted in the flow charts in FIGS. 1, 2 and 3. Thus, the invention is limited only by the following claims and their equivalents.

1. A back-illuminated image sensor configured to sense at least one of deep ultraviolet (DUV) radiation and vacuum ultraviolet (VUV) radiation, the image sensor comprising:
a semiconductor membrane having a frontside surface and an opposing backside surface;
front-end circuit structures disposed on the frontside surface;
a pure boron coating disposed on the backside surface;
a protective layer disposed on the pure boron coating; and
a fluoride-based anti-reflection coating disposed on the protective layer,
wherein the protective layer comprises one of an oxide film and a nitride film having a thickness in the range of 0.5 nm and 10 nm.

2. The image sensor of claim 1, wherein the semiconductor membrane comprises an epitaxial layer having a thickness in the range of 10 μm to 100 μm.

3. The image sensor of claim 1, wherein the pure boron coating has a thickness in the range of 2 nm to 20 nm.

4. The image sensor of claim 3 wherein the protective layer comprises one of Al₂O₃, MgO, La₂O₃, Li₂O, CaO, BeO, HfO₂, AlN, Li₃N, LaN, Mg₃N₂, HAN and Ca₃N₂.

5. The image sensor of claim 4 wherein the protective layer comprises one of Al₂O₃ and AlN and has a thickness in the range of 0.5 nm and 5 nm.

6. The image sensor of claim 4 wherein the fluoride-based antireflection coating comprises one of AlF₃, MgF₂, CaF₂, LaF₃, LiF, and HfF₄ and has a thickness in the range of 2 nm and 40 nm.

7. A method of fabricating an image sensor configured to sense at least one of deep ultraviolet (DUV) radiation and vacuum ultraviolet (VUV) radiation, the method comprising:
forming front-end circuit structures on a first surface of a semiconductor membrane;
forming a pure boron coating on a second surface of the semiconductor membrane;
forming a protective layer on the pure boron coating; and
forming a fluoride-based anti-reflection coating on the protective layer,
wherein the protective layer comprises one of an oxide film and a nitride film and has a thickness in the range of 0.5 nm and 50 nm.

8. The method of claim 7, wherein forming said pure boron coating comprises depositing one or more layers of amorphous boron on the second surface until the pure boron coating has a total thickness in the range of 2 nm to 20 nm.

9. The method of claim 8,
wherein forming said pure boron coating comprises utilizing a high temperature deposition process, and
wherein the method further comprises forming metal interconnects over the front-end circuit structures after forming said pure boron coating.

10. The method of claim 8,
wherein the method further comprises forming metal interconnects over the front-end circuit structures before forming said pure boron coating, and
wherein forming said pure boron coating comprises utilizing a low temperature deposition process.

11. The method of claim 7, wherein forming the protective layer comprises depositing at least one of Al₂O₃, MgO, La₂O₃, Li₂O, CaO, BeO, HfO₂, AlN, Li₃N, LaN, Mg₃N₂, HAN and Ca₃N₂ on an upper surface of the pure boron coating.

12. The method of claim 7,
wherein forming the protection layer comprises depositing said one of said oxide film and said nitride film such that said thickness is in the range of 0.5 nm to 10 nm, and
wherein forming the fluoride-based anti-reflective coating comprises depositing one or more fluoride-based materials onto the protection layer.

13. The method of claim 12, wherein depositing one or more fluoride-based materials comprises depositing at least one of AlF₃, MgF₂, CaF₂, LaF₃, LiF and HfF₄.

14. The method of claim 7,
wherein forming the protection layer comprises depositing said one of said oxide film and said nitride film with a total thickness in the range of 10 nm to 50 nm, and
wherein forming the fluoride-based anti-reflective coating comprises utilizing a fluorination process to convert an upper region of the protection layer into the fluoride-based anti-reflection coating.

15. The method of claim 14, wherein utilizing said fluorination process comprises exposing the protection layer to at least one fluorine-containing gas.

16. The method of claim 15, wherein utilizing the fluorination process comprises using a plasma process.

17. The method of claim 7, wherein said semiconductor membrane includes a p-doped epitaxial silicon layer disposed on a silicon substrate, and wherein the method further comprises back-thinning at least a portion of the silicon substrate to expose at least a portion of the p-doped epitaxial silicon layer, where said exposed portion of the p-doped epitaxial silicon layer forms the second surface of said semiconductor membrane.

18. The method of claim 7,
wherein said semiconductor membrane includes a p-doped epitaxial silicon layer formed on a top silicon substrate of a silicon-on-insulator (SOI) structure, the p-doped epitaxial silicon layer having a first p-type doping concentration and the top silicon substrate having a second p-type doping concentration that is greater than the first p-type doping concentration,
wherein forming the front-end circuit structures on the first surface of the semiconductor membrane comprises forming the front-end circuit structures on the p-doped epitaxial silicon layer, and
wherein forming the pure boron coating on the second surface of the semiconductor membrane comprises:
removing at least a portion of a handle substrate and oxide layer of the SOI structure to expose one or more surface portions of the top silicon substrate; and
forming the pure boron coating on the exposed surface portions.

19. The method of claim 18, wherein the method further comprises forming through-silicon vias in the semiconductor membrane before forming the pure boron coating.

20. An inspection system comprising: an illumination source; a set of optics including an objective lens configured to direct and focus incident light from the illumination source onto a sample and to collect, direct, and focus reflected/scattered light from the sample onto a detector assembly, wherein the detector includes one or more image sensors configured to sense at least one of deep ultraviolet (DUV) radiation and vacuum ultraviolet (VUV) radiation,
wherein each said image sensor comprises a semiconductor membrane, circuit elements formed on a first surface of the semiconductor membrane, at least one pure boron layer formed on a second surface of the semiconductor membrane, a protective layer formed on the pure boron layer, and a fluoride-based antireflection coating disposed over the protective layer, and
wherein the protective layer comprises one of an oxide and a nitride and has a thickness in the range of 0.5 nm and 10 nm.
